(19) United States
(12) Patent Application Publication
(10) Pub. No.: US 2021/0360783 A1
(43) Pub. Date: Nov. 18, 2021

(54) CONDUCTIVE GLASS SUBSTRATE, AND SYSTEM AND METHOD FOR MANUFACTURING THE SAME

(71) Applicant: ASTI GLOBAL INC., TAIWAN, Taichung City (TW)

(72) Inventor: CHIEN-SHOU LIAO, New Taipei City (TW)

(21) Appl. No.: 17/316,915

(22) Filed: May 11, 2021

(30) Foreign Application Priority Data
May 12, 2020 (TW) 109115672

(51) Int. Cl. H05K 1/03; C03C 23/00; H05K 1/11

(52) U.S. Cl. CPC H05K 1/0306; H05K 2201/095; H05K 1/115; C03C 23/0025

(57) ABSTRACT

A conductive glass substrate, and a system and a method for manufacturing the same are provided. The conductive glass substrate includes a glass substrate structure, a conductive base structure and a conductive extending structure. The glass substrate structure includes at least one through hole connected between a bottom surface and a top surface thereof. The conductive base structure is disposed on the bottom surface of the glass substrate structure. The conductive extending structure is electrically connected to the conductive base structure, and the conductive extending structure is extended from the conductive base structure to the top surface of the glass substrate structure along an inner surface of the at least one through hole. Hence, the conductive glass substrate can provide at least one conductive via so as to electrically connect an upper circuit and a lower circuit.

### CROSS-REFERENCE TO RELATED PATENT APPLICATION

This application claims the benefit of priority to Taiwan Patent Application No. 109115672, filed on May 12, 2020. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a glass substrate, and a system and a method for manufacturing the same, and more particularly to a conductive glass substrate, and a system and a method for manufacturing the same.

### BACKGROUND OF THE DISCLOSURE

In the related art, it is quite difficult to manufacture a conductive via that penetrates through a glass substrate.

### SUMMARY OF THE DISCLOSURE

In response to the above-referenced technical inadequacy, the present disclosure provides a conductive glass substrate, and a system and a method for manufacturing the same.

In one aspect, the present disclosure provides a conductive glass substrate including a glass substrate structure, a conductive base structure and a conductive extending structure. The glass substrate structure has a bottom surface and a top surface corresponding to the bottom surface, and the glass substrate structure includes at least one through hole connected between the bottom surface and the top surface of the glass substrate structure. The conductive base structure is disposed on the bottom surface of the glass substrate structure. The conductive extending structure is electrically connected to the conductive base structure, and the conductive extending structure is extended from the conductive base structure to the top surface of the glass substrate structure along an inner surface of the at least one through hole.

In another aspect, the present disclosure provides a system for manufacturing a conductive glass substrate, including a laser processing device, a conductive base material forming device, a substrate carrying device and a conductive extending material forming device. The laser processing device is used for providing a laser beam that passes through a glass substrate structure so as to form at least one through hole penetrating through the glass substrate structure. The conductive base material forming device is used for forming a conductive base structure, and the conductive base structure is disposed on a bottom surface of the glass substrate structure. The substrate carrying device is used for carrying the glass substrate structure having the conductive base structure, and the conductive base structure is disposed between the glass substrate structure and the substrate carrying device. The conductive extending material forming device is used for forming a conductive extending structure that is electrically connected to the conductive base structure, and the conductive extending structure is extended from the conductive base structure to a top surface of the glass substrate structure along an inner surface of the at least one through hole. The laser processing device, the conductive base material forming device, the substrate carrying device, and the conductive extending material forming device are disposed on a same production line.

In yet another aspect, the present disclosure provides a method for manufacturing a conductive glass substrate including: providing a composite substrate, in which the composite substrate includes a glass substrate structure having at least one through hole, and a conductive base structure disposed on a bottom surface of the glass substrate structure; and then forming a conductive extending structure electrically connected to the conductive base structure, in which the conductive extending structure is extended from the conductive base structure to a top surface of the glass substrate structure along an inner surface of the at least one through hole.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a method for manufacturing a conductive glass substrate according to the present disclosure;

FIG. 2 is a schematic view of step S100 and step S200 of the method for manufacturing the conductive glass substrate according to the present disclosure;

FIG. 3 is a schematic view of step S102 of the method for manufacturing the conductive glass substrate according to the present disclosure;

FIG. 4 is a schematic view of step S104 of the method for manufacturing the conductive glass substrate according to the present disclosure;

FIG. 5 is a schematic view of step S106 of the method for manufacturing the conductive glass substrate according to the present disclosure;

FIG. 6 is a schematic cross-sectional view of the conductive glass substrate according to a first embodiment of the present disclosure;

FIG. 7 is a schematic enlarged view of part VII of FIG. 6;

FIG. 8 is a schematic view of a conductive extending structure including a conductive buried portion for filling up at least one through hole, and a conductive exposed portion connected to the conductive buried portion according to a second embodiment of the present disclosure;

FIG. 9 is a schematic cross-sectional view of a conductive glass substrate according to the second embodiment of the present disclosure;

FIG. 10 is a schematic view of step S202 of the method for manufacturing the conductive glass substrate according to the present disclosure;

FIG. 11 is a schematic view of step S204 of the method for manufacturing the conductive glass substrate according to the present disclosure;

FIG. 12 is a schematic view of step S206 of the method for manufacturing the conductive glass substrate according to the present disclosure;

FIG. 13 is a schematic cross-sectional view of a conductive base material forming device for forming a conductive base structure on a substrate carrying device according to a fourth embodiment of the present disclosure;

FIG. 14 is a schematic cross-sectional view of the conductive base structure being adhered to a bottom surface of a glass substrate structure by moving of a substrate carrying device according to the fourth embodiment of the present disclosure;

FIG. 15 is a schematic cross-sectional view of a conductive extending material forming device for forming a conductive extending structure electrically connected to the conductive base structure according to the fourth embodiment of the present disclosure;

FIG. 16 is a schematic view of step S300 of the method for manufacturing the conductive glass substrate according to the present disclosure;

FIG. 17 is a schematic view of step S302 of the method for manufacturing the conductive glass substrate according to the present disclosure; and

FIG. 18 is a schematic view of step S304 of the method for manufacturing the conductive glass substrate according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

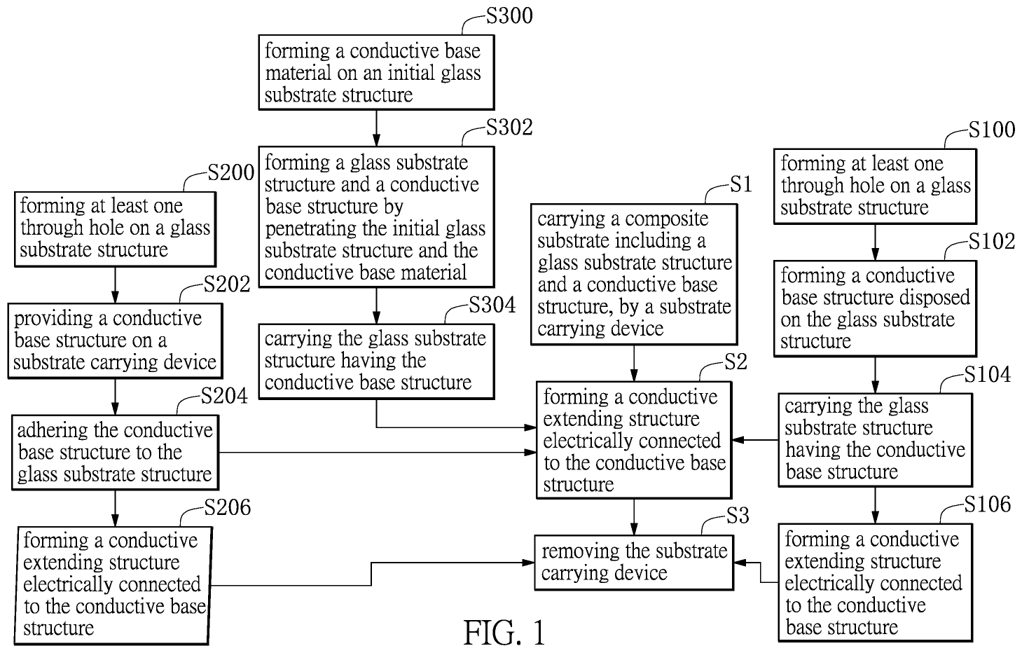

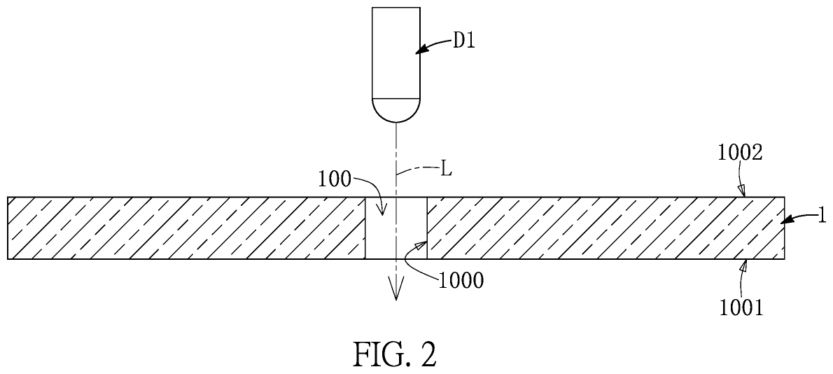

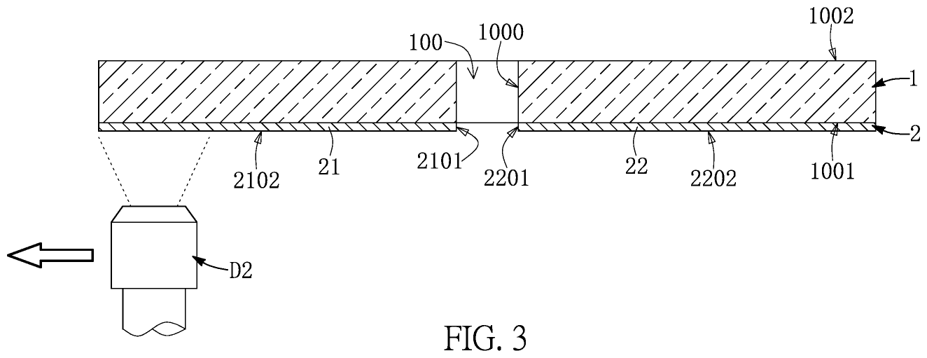

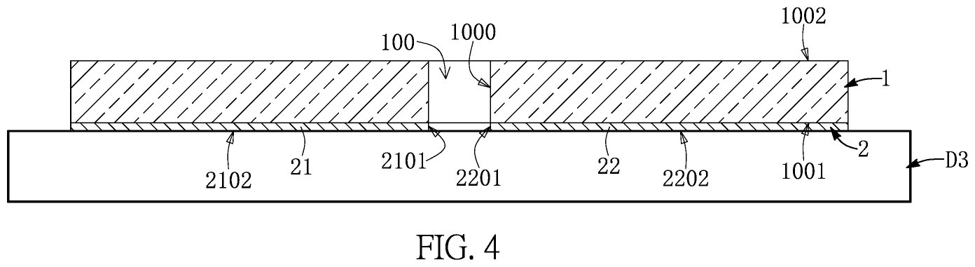

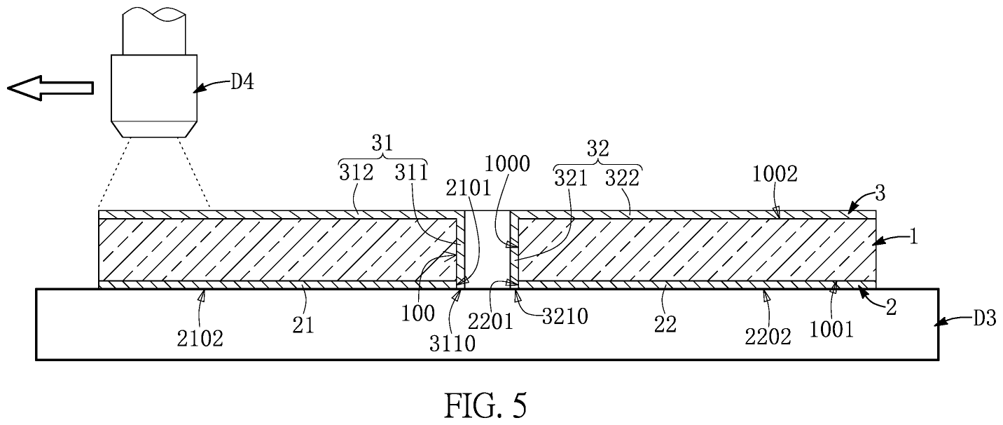

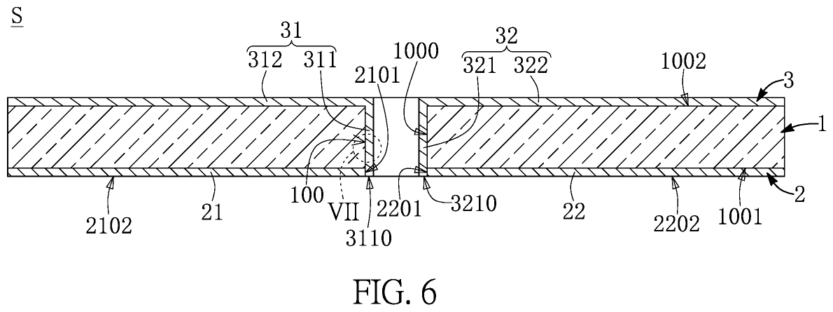

Referring to FIG. 1 to FIG. 7, a first embodiment of the present disclosure provides a method for manufacturing a conductive glass substrate S including: firstly, referring to FIG. 1 and FIG. 2, forming at least one through hole 100 on a glass substrate structure 1 by a laser beam L that is generated by a laser process device D1 (step S100); next, referring to FIG. 1 and FIG. 3, forming a conductive base structure 2 disposed on a bottom surface 1001 of the glass substrate structure 1 by a conductive base material forming device D2 (step S102); then, referring to FIG. 1 and FIG. 4, carrying the glass substrate structure 1 having the conductive base structure 2 by a substrate carrying device D3 (step S104); afterwards, referring to FIG. 1 and FIG. 5, forming a conductive extending structure 3 electrically connected to the conductive base structure 2 by a conductive extending material forming device D4, the conductive extending structure 3 extending from the conductive base structure 2 to a top surface 1002 of the glass substrate structure 1 along an inner surface 1000 of the at least one through hole 100 (step S106); and then referring to FIG. 1 and FIG. 6, removing the substrate carrying device D3 to obtain the conductive glass substrate S.

More particularly, referring to FIG. 2 to FIG. 5, the first embodiment of the present disclosure further provides a system for manufacturing a conductive glass substrate, including a laser processing device D1, a conductive base material forming device D2, a substrate carrying device D3 and a conductive extending material forming device D4, and the laser processing device D1, the conductive base material forming device D2, the substrate carrying device D3, and the conductive extending material forming device D4 are disposed on a same production line.

Moreover, as shown in FIG. 2, the laser processing device D1 can be used for providing a laser beam L1 that can pass through a glass substrate structure 1 so as to form at least one through hole 100 penetrating through the glass substrate structure 1. For example, the laser processing device D1 can be replaced by any through hole forming device. In addition, as shown in FIG. 3, the conductive base material forming device D2 can be used for forming a conductive base structure 2 on a bottom surface 1001 of the glass substrate structure 1. For example, the conductive base material forming device D2 can be a conductive material printing device, a conductive material coating device, a conductive material electroplating device, a conductive material sputtering device, a chemical vapor deposition device or a physical vapor deposition device. That is to say, the conductive base structure 2 can be formed on the bottom surface 1001 of the glass substrate structure 1 by printing, coating, electroplating, sputtering or vapor depositing. However, the aforementioned description is merely an example and is not meant to limit the scope of the present disclosure.

Furthermore, as shown in FIG. 4, the substrate carrying device D3 can be used for carrying the glass substrate structure 1 having the conductive base structure 2, and the conductive base structure 2 is disposed between the glass substrate structure 1 and the substrate carrying device D3. In addition, as shown in FIG. 5, the conductive extending material forming device D4 can be used for forming a conductive extending structure 3 that is electrically connected to the conductive base structure 2, and the conductive extending structure 3 can be extended from the conductive base structure 2 to a top surface 1002 of the glass substrate structure 1 along an inner surface 1000 of the at least one through hole 100. For example, the conductive extending material forming device D4 can be a conductive material printing device, a conductive material coating device, a conductive material electroplating device, a conductive material sputtering device, a chemical vapor deposition device or a physical vapor deposition device. That is to say, the conductive extending structure 3 can be formed on the inner surface 1000 of the at least one through hole 100 and the top surface 1002 of the glass substrate structure 1 by printing, coating, electroplating, sputtering or vapor depositing. However, the aforementioned description is merely an example and is not meant to limit the scope of the present disclosure.

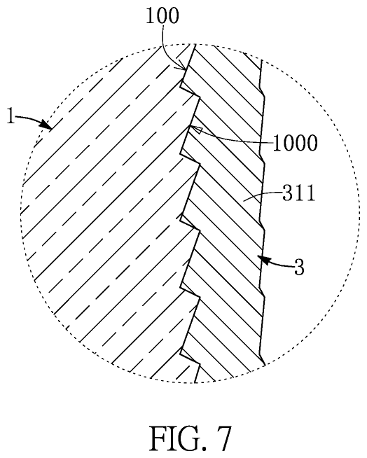

More particularly, referring to FIG. 6 and FIG. 7, the first embodiment of the present disclosure provides a conductive glass substrate S including a glass substrate structure 1, a conductive base structure 2 and a conductive extending structure 3. The glass substrate structure 1 has a bottom surface 1001 and a top surface 1002 corresponding to the bottom surface 1001, and the glass substrate structure 1 includes at least one through hole 100 connected between the bottom surface 1001 and the top surface 1002 of the glass substrate structure 1. The conductive base structure 2 is disposed on the bottom surface 1001 of the glass substrate structure 1. The conductive extending structure 3 is electrically connected to the conductive base structure 2, and the conductive extending structure 3 can be extended from the conductive base structure 2 to the top surface 1002 of the glass substrate structure 1 along an inner surface 1000 of the at least one through hole 100. It should be noted that the glass substrate structure 1 and the conductive base structure 2 can cooperate with each other to form a composite substrate.

For example, referring to FIG. 3, FIG. 6 and FIG. 7, the conductive base structure 2 includes a first conductive base layer 21 disposed on the bottom surface 1001 of the glass substrate structure 1 and a second conductive base layer 22 disposed on the bottom surface 1001 of the glass substrate structure 1, and the first conductive base layer 21 and the second conductive base layer 22 are separate from each other. In addition, the first conductive base layer 21 and the second conductive base layer 22 are directly disposed on the bottom surface 1001 of the glass substrate structure 1 so as to directly contact the bottom surface 1001 of the glass substrate structure 1. Moreover, an inner lateral surface 2101 of the first conductive base layer 21 and the inner surface 1000 of the at least one through hole 100 can be flush with each other, and an inner lateral surface 2201 of the second conductive base layer 22 and the inner surface 1000 of the at least one through hole 100 can be flush with each other. However, the aforementioned description is merely an example and is not meant to limit the scope of the present disclosure.

For example, referring to FIG. 6 and FIG. 7, the conductive extending structure 3 includes a first conductive extending layer 31 electrically connected to the first conductive base layer 21, and a second conductive extending layer 32 electrically connected to the second conductive base layer 22, and the first conductive extending layer 31 and the second conductive extending layer 32 are separate from each other or connected with each other. In addition, the first conductive extending layer 31 includes a first conductive buried portion 311 disposed on the inner surface 1000 of the at least one through hole 100, and a first conductive exposed portion 312 disposed on the top surface 1002 of the glass substrate structure 1 and connected to the first conductive buried portion 311. Moreover, the second conductive extending layer 32 includes a second conductive buried portion 321 disposed on the inner surface 1000 of the at least one through hole 100, and a second conductive exposed portion 322 disposed on the top surface 1002 of the glass substrate structure 1 and connected to the second conductive buried portion 321. However, the aforementioned description is merely an example and is not meant to limit the scope of the present disclosure.

For example, an inner lateral surface 2101 of the first conductive base layer 21 can be covered by the first conductive buried portion 311, and a bottom side 3110 of the first conductive buried portion 311 and a bottom surface 2102 of the first conductive base layer 21 can be flush with each other. In addition, an inner lateral surface 2201 of the second conductive base layer 22 can be covered by the second conductive buried portion 321, and a bottom side 3210 of the second conductive buried portion 321 and a bottom surface 2202 of the second conductive base layer 22 can be flush with each other. It should be noted that as shown in FIG. 7, when the at least one through hole 100 of the glass substrate structure 1 is formed by the laser processing device D1, the inner surface 1000 of the at least one through hole 100 can be a rough surface formed by a laser process or an irregular surface for increasing a contact area between the first conductive buried portion 311 (or the second conductive buried portion 321) of the conductive extending structure 3 and the inner surface 1000 of the at least one through hole 100. However, the aforementioned description is merely an example and is not meant to limit the scope of the present disclosure.

### Second Embodiment

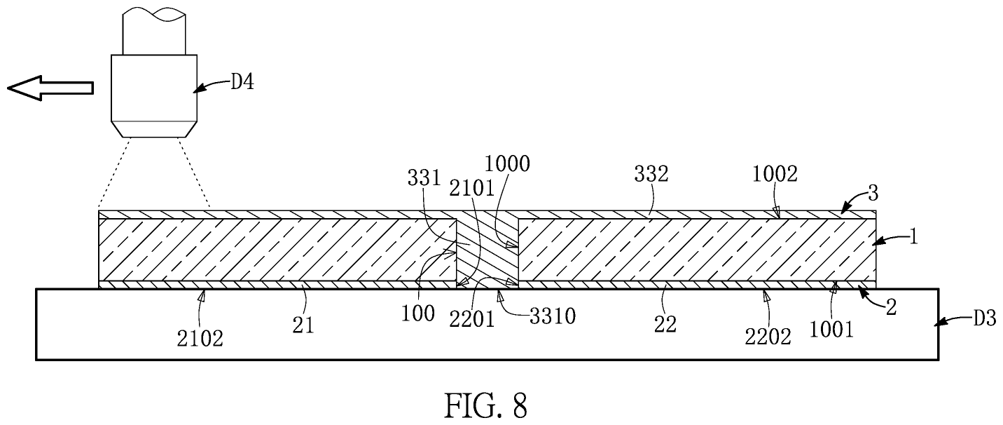

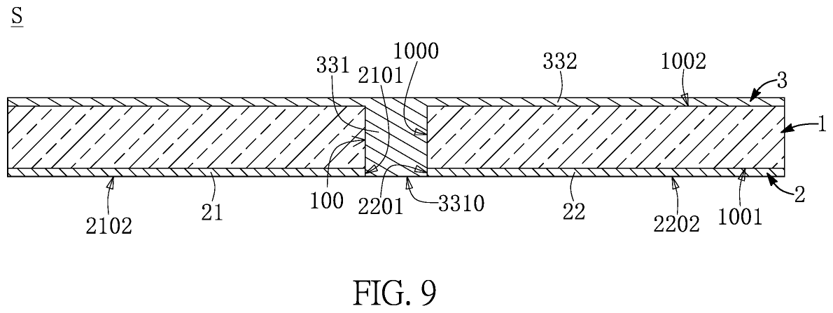

Referring to FIG. 1 to FIG. 4, FIG. 8 and FIG. 9, a second embodiment of the present disclosure provides a conductive glass substrate S, and a system and a method for manufacturing the same. Comparing FIG. 8 with FIG. 5, and comparing FIG. 9 with FIG. 6, the difference between the second embodiment and the first embodiment is as follows: in the second embodiment, the conductive extending structure 3 includes a conductive buried portion 331 and a conductive exposed portion 332 connected to the conductive buried portion 331. In addition, the conductive buried portion 331 can fill up the at least one through hole 100 and connect to the first conductive base layer 21 and the second conductive base layer 22 of the conductive base structure 2, and the conductive exposed portion 332 is disposed on the top surface 1002 of the glass substrate structure 1 so as to cover the conductive buried portion 331. Moreover, an inner lateral surface 2101 of the first conductive base layer 21 and an inner lateral surface 2201 of the second conductive base layer 22 can be covered by the conductive buried portion 331, and a bottom side 3310 of the conductive buried portion 331 and a bottom surface 2102 of the first conductive base layer 21 (or a bottom surface 2202 of the second conductive base layer 22) can be flush with each other.

### Third Embodiment

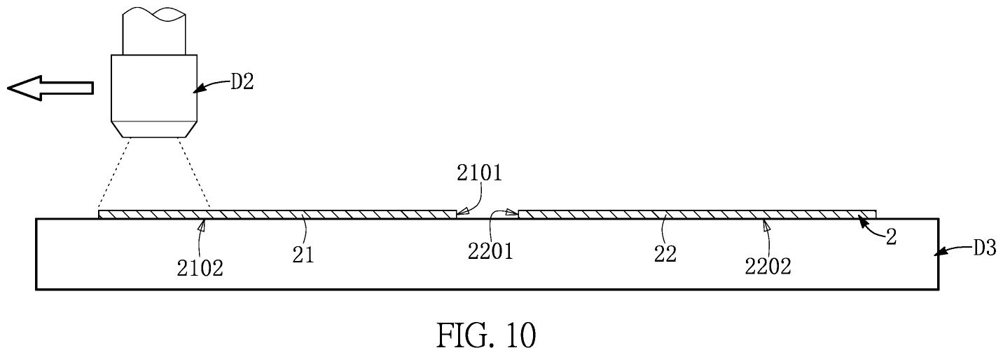

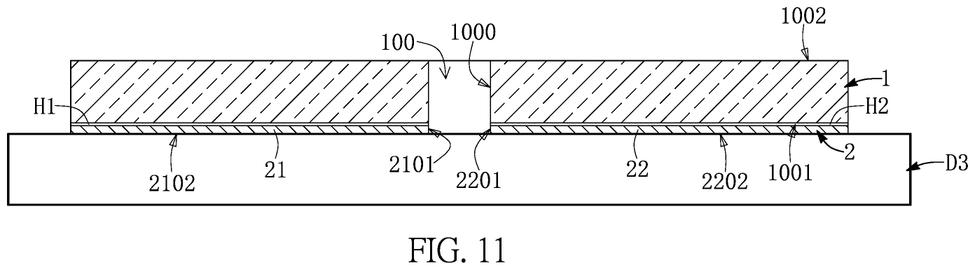

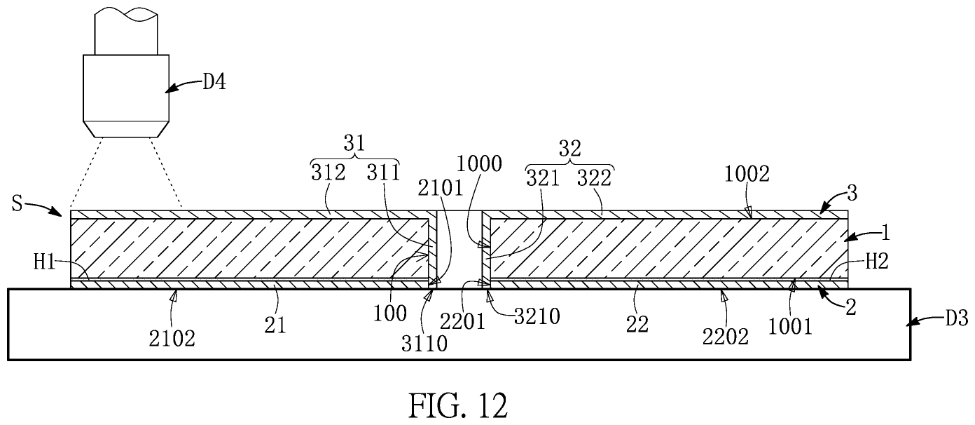

Referring to FIG. 1, FIG. 2 and FIG. 10 to FIG. 12, a third embodiment of the present disclosure provides a method for manufacturing a conductive glass substrate S including: firstly, referring to FIG. 1 and FIG. 2, forming at least one through hole 100 on a glass substrate structure 1 by a laser beam L that is generated by a laser process device D1 (step S200); next, referring to FIG. 1 and FIG. 10, providing a conductive base structure 2 on a substrate carrying device D3 by a conductive base material forming device D2 (step S202); then, referring to FIG. 1 and FIG. 11, adhering the conductive base structure 2 to a bottom surface 1001 of the glass substrate structure 1 by moving of the substrate carrying device D3 (for example, by cooperation of a first adhesive layer H1 and a second adhesive layer H2) (step S204); afterwards, referring to FIG. 1 and FIG. 12, forming a conductive extending structure 3 electrically connected to the conductive base structure 2 by a conductive extending material forming device D4, the conductive extending structure 3 being extended from the conductive base structure 2 to a top surface 1002 of the glass substrate structure 1 along an inner surface 1000 of the at least one through hole 100 (step S206); and then referring to FIG. 1 and FIG. 6, removing the substrate carrying device D3 (for example, concurrently removing the first adhesive layer H1 and the second adhesive layer H2) to obtain the conductive glass substrate S. For example, in the step S202, the conductive base structure 2 can be formed by the conductive base material forming device D2 in advance, and then the conductive base structure 2 can be adhered to the bottom surface 1001 of the glass substrate structure 1 by adhesion.

More particularly, referring to FIG. 2, and FIG. 10 to FIG. 12, the third embodiment of the present disclosure further provides a system for manufacturing a conductive glass substrate, including a laser processing device D1, a conductive base material forming device D2, a substrate carrying device D3 and a conductive extending material forming device D4, and the laser processing device D1, the conductive base material forming device D2, the substrate carrying device D3, and the conductive extending material forming device D4 are disposed on a same production line.

Moreover, as shown in FIG. 10, the conductive base structure 2 can be formed by the conductive base material forming device D2 in advance, and then the conductive base structure 2 can be adhered to the bottom surface 1001 of the glass substrate structure 1 by adhesion. In addition, as shown in FIG. 12, the conductive extending material forming device D4 can be used for forming a conductive extending structure 3 that is electrically connected to the conductive base structure 2, and the conductive extending structure 3 can be extended from the conductive base structure 2 to a top surface 1002 of the glass substrate structure 1 along an inner surface 1000 of the at least one through hole 100. For example, the conductive extending material forming device D4 can be a conductive material printing device, a conductive material coating device, a conductive material electroplating device, a conductive material sputtering device, a chemical vapor deposition device or a physical vapor deposition device. That is to say, the conductive extending structure 3 can be formed on the inner surface 1000 of the at least one through hole 100 and the top surface 1002 of the glass substrate structure 1 by printing, coating, electroplating, sputtering or vapor depositing. However, the aforementioned description is merely an example and is not meant to limit the scope of the present disclosure.

More particularly, referring to FIG. 12, the third embodiment of the present disclosure provides a conductive glass substrate S including a glass substrate structure 1, a conductive base structure 2 and a conductive extending structure 3. The glass substrate structure 1 has a bottom surface 1001 and a top surface 1002 corresponding to the bottom surface 1001, and the glass substrate structure 1 includes at least one through hole 100 connected between the bottom surface 1001 and the top surface 1002 of the glass substrate structure 1. The conductive base structure 2 is disposed on the bottom surface 1001 of the glass substrate structure 1. The conductive extending structure 3 is electrically connected to the conductive base structure 2, and the conductive extending structure 3 can be extended from the conductive base structure 2 to the top surface 1002 of the glass substrate structure 1 along an inner surface 1000 of the at least one through hole 100.

For example, referring to FIG. 12, the conductive base structure 2 includes a first conductive base layer 21 disposed on the bottom surface 1001 of the glass substrate structure 1 and a second conductive base layer 22 disposed on the bottom surface 1001 of the glass substrate structure 1, and the first conductive base layer 21 and the second conductive base layer 22 are separate from each other. In addition, the first conductive base layer 21 and the second conductive base layer 22 of the conductive base structure 2 can be indirectly disposed on the bottom surface 1001 of the glass substrate structure 1 through a first adhesive layer H1 and a second adhesive layer H2, respectively. Moreover, an inner lateral surface 2101 of the first conductive base layer 21 and the inner surface 1000 of the at least one through hole 100 can be flush with each other, and an inner lateral surface 2201 of the second conductive base layer 22 and the inner surface 1000 of the at least one through hole 100 can be flush with each other. However, the aforementioned description is merely an example and is not meant to limit the scope of the present disclosure.

For example, referring to FIG. 12, the conductive extending structure 3 includes a first conductive extending layer 31 electrically connected to the first conductive base layer 21, and a second conductive extending layer 32 electrically connected to the second conductive base layer 22, and the first conductive extending layer 31 and the second conductive extending layer 32 are separate from each other. In addition, the first conductive extending layer 31 includes a first conductive buried portion 311 disposed on the inner surface 1000 of the at least one through hole 100, and a first conductive exposed portion 312 disposed on the top surface 1002 of the glass substrate structure 1 and connected to the first conductive buried portion 311. Moreover, the second conductive extending layer 32 includes a second conductive buried portion 321 disposed on the inner surface 1000 of the at least one through hole 100, and a second conductive exposed portion 322 disposed on the top surface 1002 of the glass substrate structure 1 and connected to the second conductive buried portion 321. However, the aforementioned description is merely an example and is not meant to limit the scope of the present disclosure.

For example, referring to FIG. 12, an inner lateral surface 2101 of the first conductive base layer 21 can be covered by the first conductive buried portion 311, and a bottom side 3110 of the first conductive buried portion 311 and a bottom surface 2102 of the first conductive base layer 21 can be flush with each other. In addition, an inner lateral surface 2201 of the second conductive base layer 22 can be covered by the second conductive buried portion 321, and a bottom side 3210 of the second conductive buried portion 321 and a bottom surface 2202 of the second conductive base layer 22 can be flush with each other. However, the aforementioned description is merely an example and is not meant to limit the scope of the present disclosure.

### Fourth Embodiment

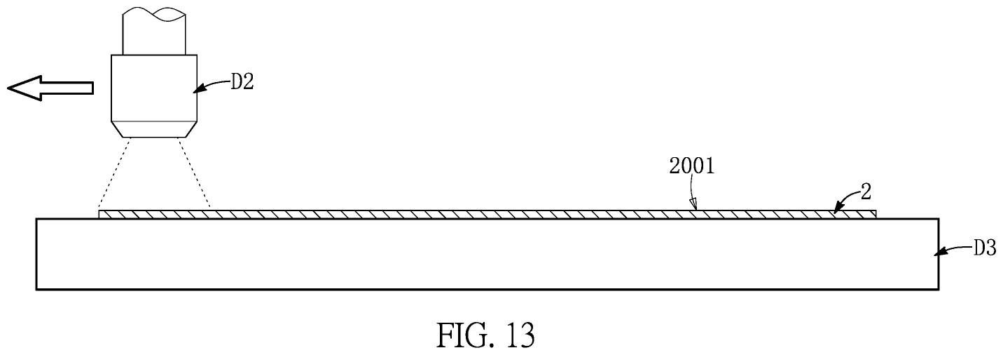

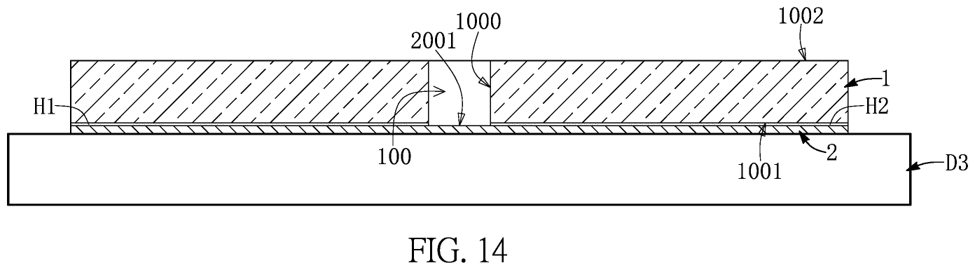

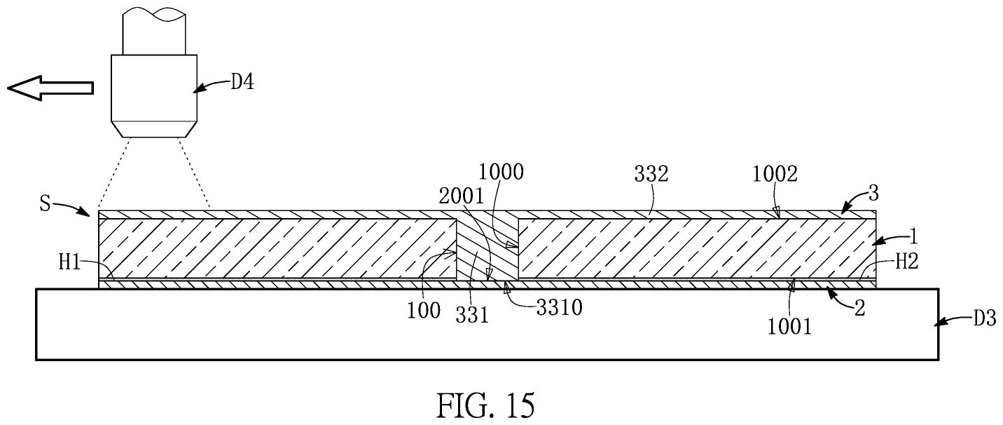

Referring to FIG. 13 to FIG. 15, a fourth embodiment of the present disclosure provides a conductive glass substrate S, and a system and a method for manufacturing the same. Comparing FIG. 13 with FIG. 10, comparing FIG. 14 with FIG. 11, and comparing FIG. 15 with FIG. 12, the difference between the fourth embodiment and the third embodiment is as follows: in the fourth embodiment, the conductive base structure 2 is a single conductive base layer (or an integrated conductive base layer). More particularly, the conductive extending structure 3 includes a conductive buried portion 331 and a conductive exposed portion 332 connected to the conductive buried portion 331. In addition, the conductive buried portion 331 can fill up the at least one through hole 100 and connect to the first conductive base layer 21 and the second conductive base layer 22 of the conductive base structure 2, and the conductive exposed portion 332 is disposed on the top surface 1002 of the glass substrate structure 1 so as to cover the conductive buried portion 331. Moreover, a bottom side 3310 of the conductive buried portion 331 and a top surface 2001 of the conductive base structure 2 can be flush with each other.

### Fifth Embodiment

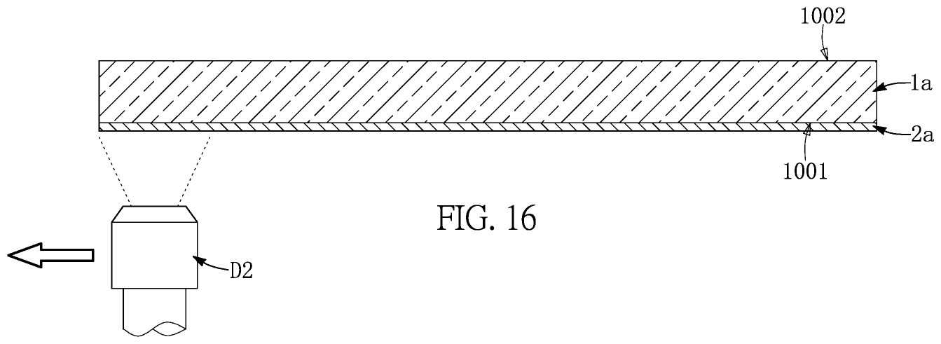

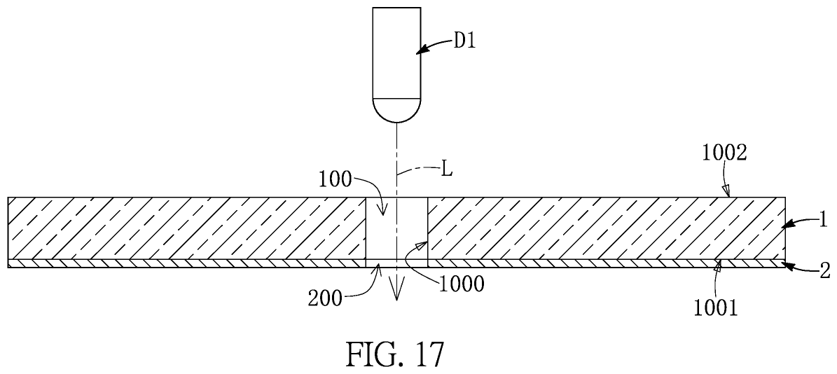

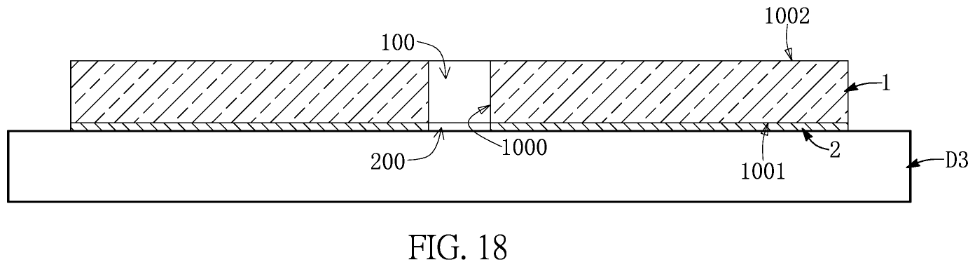

Referring to FIG. 1, and FIG. 16 to FIG. 18, a fifth embodiment of the present disclosure provides a method for manufacturing a conductive glass substrate S including: firstly, referring to FIG. 1 and FIG. 16, forming a conductive base material 2a on a bottom surface 1001 of an initial glass substrate structure 1a by a conductive base material forming device D2 (step S300); next, referring to FIG. 1 and FIG. 17, forming a glass substrate structure 1 having at least one through hole 100, and a conductive base structure 2 having at least one through hole 200, by penetrating the initial glass substrate structure 1a and the conductive base material 2a by a laser beam L that is generated by a laser process device D1, respectively (step S302); and then referring to FIG. 1 and FIG. 18, carrying the glass substrate structure 1 having the conductive base structure 2 by a substrate carrying device D3 (step S304).

### Beneficial Effects of the Embodiments

In conclusion, by virtue of “the glass substrate structure 1 including at least one through hole 100 connected between the bottom surface 1001 and the top surface 1002 thereof”, “the conductive base structure 2 being disposed on the bottom surface 1001 of the glass substrate structure 1” and “the conductive extending structure 3 being electrically connected to the conductive base structure 2, and the conductive extending structure 3 being extended from the conductive base structure 2 to the top surface 1002 of the glass substrate structure 1 along an inner surface 1000 of the at least one through hole 100”, the conductive glass substrate S can provide at least one conductive via (that is one part of the conductive extending structure 3 disposed inside the at least one through hole) so as to electrically connect an upper circuit (that is another part of the conductive extending structure 3 disposed on the top surface 1002 of the glass substrate structure 1) and a lower circuit (that is the conductive base structure 2 disposed on the bottom surface 1001 of the glass substrate structure 1).

Furthermore, by virtue of “the laser processing device D1 being used for providing a laser beam L that passes through a glass substrate structure 1 so as to form at least one through hole 100 penetrating through the glass substrate structure 1”, “the conductive base material forming device D2 being used for forming a conductive base structure 2 that is disposed on a bottom surface 1001 of the glass substrate structure 1”, “the substrate carrying device D3 being used for carrying the glass substrate structure 1 having the conductive base structure 2” and “the conductive extending material forming device D4 being used for forming a conductive extending structure 3 that is electrically connected to the conductive base structure 2, and the conductive extending structure 3 being extended from the conductive base structure 2 to a top surface 1002 of the glass substrate structure 1 along an inner surface 1000 of the at least one through hole 100”, the conductive glass substrate S can provide at least one conductive via (that is one part of the conductive extending structure 3 disposed inside the at least one through hole) so as to electrically connect an upper circuit (that is another part of the conductive extending structure 3 disposed on the top surface 1002 of the glass substrate structure 1) and a lower circuit (that is the conductive base structure 2 disposed on the bottom surface 1001 of the glass substrate structure 1).

Moreover, by virtue of “providing a composite substrate that includes a glass substrate structure 1 having at least one through hole 100, and a conductive base structure 2 disposed on a bottom surface 1001 of the glass substrate structure 1”, “forming a conductive extending structure 3 electrically connected to the conductive base structure 2, the conductive extending structure 3 being extended from the conductive base structure 2 to a top surface 1002 of the glass substrate structure 1 along an inner surface 1000 of the at least one through hole 100” and “removing the substrate carrying device D3”, the conductive glass substrate S can provide at least one conductive via (that is one part of the conductive extending structure 3 disposed inside the at least one through hole) so as to electrically connect an upper circuit (that is another part of the conductive extending structure 3 disposed on the top surface 1002 of the glass substrate structure 1) and a lower circuit (that is the conductive base structure 2 disposed on the bottom surface 1001 of the glass substrate structure 1).

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A conductive glass substrate, comprising:
a glass substrate structure having a bottom surface and a top surface corresponding to the bottom surface, wherein the glass substrate structure includes at least one through hole connected between the bottom surface and the top surface of the glass substrate structure;
a conductive base structure disposed on the bottom surface of the glass substrate structure; and
a conductive extending structure electrically connected to the conductive base structure, wherein the conductive extending structure is extended from the conductive base structure to the top surface of the glass substrate structure along an inner surface of the at least one through hole.

2. The conductive glass substrate according to claim 1, wherein the inner surface of the at least one through hole is a rough surface formed by a laser process or an irregular surface for increasing a contact area between the conductive extending structure and the inner surface of the at least one through hole.

3. The conductive glass substrate according to claim 1, wherein the conductive base structure includes a first conductive base layer disposed on the bottom surface of the glass substrate structure and a second conductive base layer disposed on the bottom surface of the glass substrate structure, and the first conductive base layer and the second conductive base layer are separate from each other.

4. The conductive glass substrate according to claim 3, wherein the first conductive base layer and the second conductive base layer are directly disposed on the bottom surface of the glass substrate structure so as to directly contact the bottom surface of the glass substrate structure, or the first conductive base layer and the second conductive base layer are indirectly disposed on the bottom surface of the glass substrate structure through a first adhesive layer and a second adhesive layer, respectively; wherein an inner lateral surface of the first conductive base layer and the inner surface of the at least one through hole are flush with each other, and an inner lateral surface of the second conductive base layer and the inner surface of the at least one through hole are flush with each other.

5. The conductive glass substrate according to claim 3, wherein the conductive extending structure includes a first conductive extending layer electrically connected to the first conductive base layer, and a second conductive extending layer electrically connected to the second conductive base layer, and the first conductive extending layer and the second conductive extending layer are separate from each other or connected with each other; wherein the first conductive extending layer includes a first conductive buried portion disposed on the inner surface of the at least one through hole, and a first conductive exposed portion disposed on the top surface of the glass substrate structure and connected to the first conductive buried portion, and the second conductive extending layer includes a second conductive buried portion disposed on the inner surface of the at least one through hole, and a second conductive exposed portion disposed on the top surface of the glass substrate structure and connected to the second conductive buried portion.

6. The conductive glass substrate according to claim 5, wherein an inner surface of the first conductive base layer is covered by the first conductive buried portion, and a bottom side of the first conductive buried portion and a bottom surface of the first conductive base layer are flush with each other; wherein an inner surface of the second conductive base layer is covered by the second conductive buried portion, and a bottom side of the second conductive buried portion and a bottom surface of the second conductive base layer are flush with each other.

7. The conductive glass substrate according to claim 1, wherein the conductive base structure is a single conductive base layer; wherein the conductive base structure is directly disposed on the bottom surface of the glass substrate structure so as to directly contact the bottom surface of the glass substrate structure, or the conductive base structure is indirectly disposed on the bottom surface of the glass substrate structure through a first adhesive layer and a second adhesive layer; wherein the conductive extending structure includes a conductive buried portion and a conductive exposed portion connected to the conductive buried portion, the conductive buried portion fills up the at least one through hole and connects to the conductive base structure, and the conductive exposed portion is disposed on the top surface of the glass substrate structure so as to cover the conductive buried portion.

8. A system for manufacturing a conductive glass substrate, comprising:
a laser processing device for providing a laser beam that passes through a glass substrate structure so as to form at least one through hole penetrating through the glass substrate structure;
a conductive base material forming device for forming a conductive base structure, wherein the conductive base structure is disposed on a bottom surface of the glass substrate structure;
a substrate carrying device for carrying the glass substrate structure having the conductive base structure, wherein the conductive base structure is disposed between the glass substrate structure and the substrate carrying device; and
a conductive extending material forming device for forming a conductive extending structure that is electrically connected to the conductive base structure, wherein the conductive extending structure is extended from the conductive base structure to a top surface of the glass substrate structure along an inner surface of the at least one through hole;
wherein the laser processing device, the conductive base material forming device, the substrate carrying device, and the conductive extending material forming device are disposed on a same production line.

9. A method for manufacturing a conductive glass substrate, comprising:
providing a composite substrate, wherein the composite substrate includes a glass substrate structure having at least one through hole, and a conductive base structure disposed on a bottom surface of the glass substrate structure; and
forming a conductive extending structure electrically connected to the conductive base structure, wherein the conductive extending structure is extended from the conductive base structure to a top surface of the glass substrate structure along an inner surface of the at least one through hole.

10. The method according to claim 9, wherein the step of providing the composite substrate further includes:
forming the at least one through hole on the glass substrate structure;
forming the conductive base structure disposed on the bottom surface of the glass substrate structure; and
carrying the glass substrate structure having the conductive base structure;
wherein the conductive extending structure is sequentially formed on the inner surface of the at least one through hole and the top surface of the glass substrate structure by electroplating.

11. The method according to claim 9, wherein the step of providing the composite substrate further comprises:
forming the at least one through hole on the glass substrate structure;
providing the conductive base structure; and
adhering the conductive base structure to the bottom surface of the glass substrate structure;
wherein the conductive extending structure is sequentially formed on the inner surface of the at least one through hole and the top surface of the glass substrate structure by electroplating.

12. The method according to claim 9, wherein the step of providing the composite substrate further comprises:
forming a conductive base material on a bottom surface of an initial glass substrate structure;
forming the glass substrate structure having the at least one through hole, and the conductive base structure, by penetrating the initial glass substrate structure and the conductive base material, respectively; and
carrying the glass substrate structure having the conductive base structure;
wherein the conductive extending structure is sequentially formed on the inner surface of the at least one through hole and the top surface of the glass substrate structure by electroplating.

13. The method according to claim 9, wherein the inner surface of the at least one through hole is a rough surface formed by a laser process or an irregular surface for increasing a contact area between the conductive extending structure and the inner surface of the at least one through hole.

14. The method according to claim 9, wherein the conductive base structure includes a first conductive base layer disposed on the bottom surface of the glass substrate structure and a second conductive base layer disposed on the bottom surface of the glass substrate structure, and the first conductive base layer and the second conductive base layer are separate from each other.

15. The method according to claim 14, wherein the first conductive base layer and the second conductive base layer are directly disposed on the bottom surface of the glass substrate structure so as to directly contact the bottom surface of the glass substrate structure, or the first conductive base layer and the second conductive base layer are indirectly disposed on the bottom surface of the glass substrate structure through a first adhesive layer and a second adhesive layer, respectively; wherein an inner lateral surface of the first conductive base layer and the inner surface of the at least one through hole are flush with each other, and an inner lateral surface of the second conductive base layer and the inner surface of the at least one through hole are flush with each other.

16. The method according to claim 14, wherein the conductive extending structure includes a first conductive extending layer electrically connected to the first conductive base layer, and a second conductive extending layer electrically connected to the second conductive base layer, and the first conductive extending layer and the second conductive extending layer are separate from each other or connected with each other; wherein the first conductive extending layer includes a first conductive buried portion disposed on the inner surface of the at least one through hole, and a first conductive exposed portion disposed on the top surface of the glass substrate structure and connected to the first conductive buried portion, and the second conductive extending layer includes a second conductive buried portion disposed on the inner surface of the at least one through hole, and a second conductive exposed portion disposed on the top surface of the glass substrate structure and connected to the second conductive buried portion.

17. The method according to claim 16, wherein an inner surface of the first conductive base layer is covered by the first conductive buried portion, and a bottom side of the first conductive buried portion and a bottom surface of the first conductive base layer are flush with each other; wherein an inner surface of the second conductive base layer is covered by the second conductive buried portion, and a bottom side of the second conductive buried portion and a bottom surface of the second conductive base layer are flush with each other.

18. The method according to claim 9, wherein the conductive base structure is a single conductive base layer; wherein the conductive base structure is directly disposed on the bottom surface of the glass substrate structure so as to directly contact the bottom surface of the glass substrate structure, or the conductive base structure is indirectly disposed on the bottom surface of the glass substrate structure through a first adhesive layer and a second adhesive layer; wherein the conductive extending structure includes a conductive buried portion and a conductive exposed portion connected to the conductive buried portion, the conductive buried portion fills up the at least one through hole and connects to the conductive base structure, and the conductive exposed portion is disposed on the top surface of the glass substrate structure so as to cover the conductive buried portion.
